(19) United States
(12) Patent Application Publication
(10) Pub. No.: US 2009/0238990 A1
(43) Pub. Date: Sep. 24, 2009

(54) SAM oxidative removal for controlled nanofabrication

(76) Inventors: Neil Dasgupta, Menlo Park, CA (US); Young Beom Kim, Menlo Park, CA (US); Wonyoung Lee, Stanford, CA (US); Friedrich R. Prinz, Woodside, CA (US)

Correspondence Address: LUMEN PATENT FIRM, 350 Cambridge, Suite 100, PALO ALTO, CA, 94306, US

(21) Appl. No.: 12/383,587

(22) Filed: Mar. 24, 2009

Related U.S. Application Data
(60) Provisional application No. 61/070,714, filed on Mar. 24, 2008.

(51) Int. Cl. B05D 3/14; C23C 16/04

(52) U.S. Cl. 427/540

(57) ABSTRACT

Improved tip-patterned atomic layer deposition (ALD) is provided by using a scanning probe microscope (SPM) tip to define an oxide pattern in a self-assembled monolayer deposited on a substrate. The oxide pattern can directly define the ALD deposition pattern. Alternatively, the oxide pattern can be removed (e.g., with a chemical etch), and the resulting exposed substrate pattern can be used to define the ALD deposition pattern.

### CROSS REFERENCE TO RELATED APPLICATIONS

This application claims the benefit of U.S. provisional patent application 61/070,714, filed on Mar. 24, 2008, entitled “SAM Oxidative Removal for Controlled Nanofabrication”, and hereby incorporated by reference in its entirety.

### FIELD OF THE INVENTION

This invention relates to lateral pattern control for atomic layer deposition.

### BACKGROUND

Atomic layer deposition is a thin film growth technique that employs a sequence of self-limiting surface reaction steps to allow sub-nanometer control of the growth process. The self-limiting adsorption reactions ensure precise control of film thickness and uniformity over large areas. For example, with ALD it is possible to ensure that growth of layer #1 is complete before growth of layer #2 on top of layer #1 is initiated. In this manner, ALD provides very accurate and precise control of device structure and composition in the growth direction (typically taken to be the z direction). However, it remains challenging to provide a comparable level of structure/composition control for ALD in the lateral directions (i.e., x and y directions).

Various methods have been investigated for providing lateral patterning capability in combination with ALD. It is important that such patterning techniques not disrupt the layer by layer growth that is characteristic of ALD, and substantial experimental investigation is typically required to confirm the suitability of any particular patterning methods for use with ALD. For example, one approach that has been experimentally investigated is the use of microcontact printed resists. Chemical resists for area-selective ALD mostly employ self-assembled monolayers (SAMs). SAMs are thin organic films which can form spontaneously on solid surfaces. SAMs can modify the physical, chemical, and electrical properties of surfaces. In particular, SAMs can inhibit surface reactions of ALD precursors. A variety of SAMs are stable at temperatures up to a few hundred degrees centigrade, unlike the resist layers used for photolithography and electron beam lithography.

Another approach which has been considered for lateral patterning combined with ALD is the use of a scanning probe microscopy (SPM) tip to add or remove passivating material from a substrate surface (U.S. Pat. No. 7,326,293). The resulting pattern of passivation material controls the lateral pattern of subsequent ALD. However, this process of directly adding or removing passivation material from the surface of a substrate can be time-consuming and/or can cause difficulties in practice (e.g., when removing passivation material from a surface, the removed material may accumulate on the tip and degrade performance).

Accordingly, it would be an advance in the art to provide a tip-patterned ALD method that does not suffer from the above-identified problems.

### SUMMARY

Improved tip-patterned atomic layer deposition is provided by using an SPM tip to define an oxide pattern in a self-assembled monolayer deposited on a substrate. The oxide pattern can directly define the ALD deposition pattern. Alternatively, the oxide pattern can be removed (e.g., with a chemical etch), and the resulting exposed substrate pattern can be used to define the ALD deposition pattern. This approach provides precise lateral control of atomic layer deposition while avoiding any problems that may arise in connection with approaches where material (i.e., atoms, molecules and/or ions) is transferred between the SPM tip and the substrate.

### BRIEF DESCRIPTION OF THE DRAWINGS

FIGS. 1a-f show side views of intermediate and final results from a process according to an embodiment of the invention.

FIGS. 2a-c show top views of intermediate and final results from a process according to an embodiment of the invention.

FIGS. 3a-b show XPS spectra of ZrO₂ deposition (a) on a bare silicon wafer (b) on an ODTS-grown silicon sample.

FIGS. 4a-c show side views of intermediate and final results from an experiment.

FIGS. 5a-d show AFM images at several points during an experimental fabrication run.

FIGS. 6a-d show characterization results from an experimental sample having an atomic layer deposition pattern.

### DETAILED DESCRIPTION

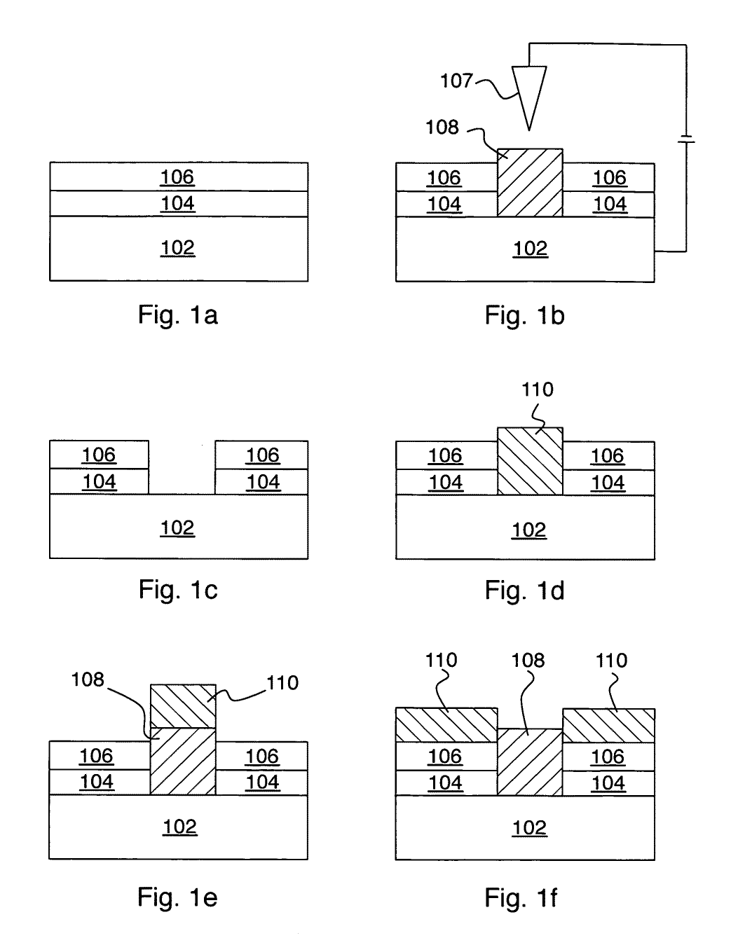

FIGS. 1a-d show side views of results of a first exemplary process sequence. FIG. 1a shows an initial configuration, where an SAM 106 is deposited on a clean silicon substrate 102. Preferably, SAM 106 is a uniform and densely packed monolayer. The native oxide of the Si substrate is shown as 104. FIG. 1b shows SPM oxidation of SAM 106. More specifically, when an electric field is applied through a conductive SPM tip 107, an anodic bias can induce local oxidation of SAM 106, forming an oxide pattern 108 while simultaneously removing SAMs that may be located on top of the created oxide pattern. Locating the AFM tip in a predefined fashion enables the creation of oxide patterns on the ODTS-grown silicon surface.

FIG. 1c shows the results of removing the oxide pattern (e.g., by hydrofluoric (HF) acid etching), thereby exposing the silicon substrate underneath, while the unoxidized part of SAM 1.06 remain undamaged by the etching. This patterned substrate can now be used as a template for further ALD processing. FIG. 1d shows the results after ALD material 110 is grown in the locations exposed by the oxide etch. After the desired ALD process is completed, the residual SAM can optionally be removed by several methods, such as oxygen plasma, ozone plasma and/or a piranha solution.

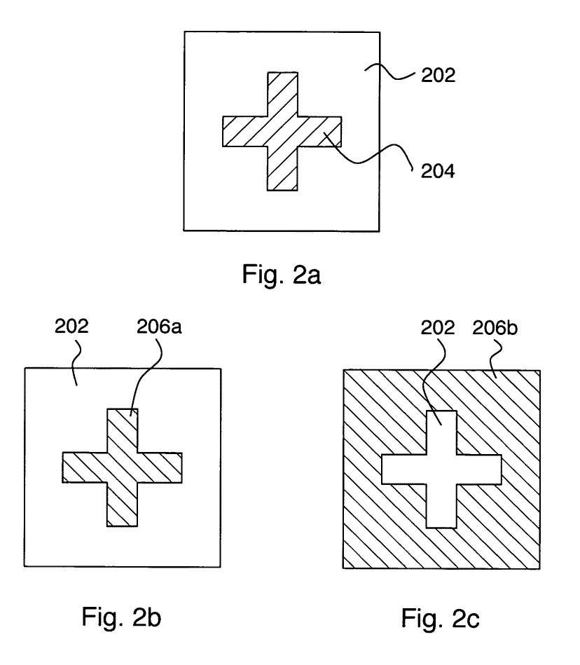

FIGS. 1e-f show some variations on this basic sequence. In the example of FIG. 1e, ALD material 110 is deposited on top of oxide 108. This approach is suitable in situations where oxide 108 as formed by SPM tip oxidation provides a suitable surface for ALD. In the example of FIG. 1f, SAM 106 enhances ALD as opposed to inhibiting it. Thus, in this example, ALD occurs at locations where SAM 106 is present in its original form after oxide patterning, and does not occur where SAM 106 is altered (or removed) after oxide patterning. This point is further described below in connection with FIGS. 2a-c.

Although any kind of SPM tip capable of locally oxidizing an SAM can be employed, preferred embodiments perform oxide lithography with an atomic force microscope (AFM) or a scanning tunneling microscope (STM). Selective oxidation can be induced by an electric field between the tip and the substrate and/or by electron transfer between tip and substrate. One or more SPM tips can be employed to generate the oxide pattern. Increasing the number of simultaneously operating SPM tips can decrease the time required to generate an oxide pattern. If multiple SPM tips are employed, they can be arranged in an array having fixed relative spacings, or they can have independently controllable positions.

Atomic layer deposition is sometimes referred to as atomic layer epitaxy (ALE) in situations where deposition is epitaxial (i.e., the grown material is crystalline and matched to a crystalline substrate). The term “atomic layer deposition” as used herein includes both epitaxial and non-epitaxial growth.

FIGS. 2a-c show top views of intermediate and final results from a process according to an embodiment of the invention. FIG. 2a shows an oxide pattern 204 formed on a substrate 202 as described above. FIGS. 2b-c show two possibilities for the ALD pattern corresponding to oxide pattern 206. In the example of FIG. 2b, ALD pattern 206a is substantially congruent to oxide pattern 204, while in the example of FIG. 2c, ALD pattern 206b is substantially congruent to the image negative of oxide pattern 204. Results as in FIG. 2b are seen in situations where the SAM inhibits ALD so that ALD only occurs where the SAM is oxidized (and optionally removed). Results as in FIG. 2c are seen in situations where the SAM enhances ALD, so that ALD occurs at all locations except where the SAM is oxidized (and optionally removed).

Experiments: The following material is a description of experiments that were performed relating to the above-described ideas. Area-selective ALD of zirconia (ZrO₂) using SAM and AFM oxidation lithography as a method of fabricating nano-structures was experimentally investigated. A SAM layer was used as a chemical mask for the ZrO₂ ALD process, and AFM oxidation lithography was used as a nano-scale patterning tool. AFM oxidation lithography was applied to create oxide patterns on ODTS SAM-grown silicon substrates. Subsequent hydrofluoric acid etching removed the oxide patterns locally, exposing a silicon substrate underneath. After 100 cycles of the ALD process, ZrO₂ ALD nano-structures of ˜7 nm in height and sub-100 nm in width were fabricated with no detectable Zr element outside the pattern defined by AFM oxidation lithography.

Preparation of ODTS SAMs. All chemicals, including ODTS (97%), toluene (anhydrous, 99.8%) and chloroform (99%), used to form SAMs were purchased from Aldrich (Milwaukee, Wis.) and used as received. All silicon pieces were cut from Si (100) wafers (p-type with boron dopant; resistivity of 0.1˜0.9 Ωcm) before cleaning. The silicon pieces were cleaned by sonication in chloroform, acetone and ethanol. This was followed by DI water rinsing and a piranha etch. After additional sonication in chloroform, acetone and ethanol were conducted, the silicon pieces were rinsed with DI water and blown dry with a nitrogen flow. The growth of the SAM was performed in a dry and air-purged glove box at room temperature. These cleaned silicon pieces were dipped in 10 mM octadecyltrichlorosilane (ODTS) solutions in toluene for more than 48 hours for conformal and dense coverage. After the desired dipping time elapsed, the samples were quickly immersed in toluene, acetone and chloroform, and blown dry with an N₂ flow before AFM oxidation lithography or ALD processing. Diluted HF acid (50:1 HF) (Fisher Scientific) etching was used to remove the oxide patterns, and this was followed by a running DI water rinse.

AFM Oxidation Lithography. A commercial AFM system (JSPM 5200, JEOL) was used for AFM lithography in contact mode with additional circuits to perform oxidation. The tips used were Pt coated silicon tips (PPP-NCHPt, Nanosensors) with a radius of ˜40 nm. The relative humidity (RH) was controlled within a range of 60˜70%. The RMS roughness of the silicon substrate was less than 1 Å, with a native oxide layer of about 2 nm. The electric pulse was controlled by the AFM system and an external circuit with 0˜10 V (the AFM tip was always grounded) and 0.05˜10 ms in magnitude and duration, respectively.

Preparation of ZrO₂ Thin Films. The samples were loaded into a custom-built, flow-type ALD system for ZrO₂ thin films. The base pressure of the ALD chamber was 2×10⁻² torr. The temperatures were set to 200° C. for the substrate, and 80° C. for the precursor. A tetrakis (dimethylamido) zirconium (Zr(NMe₂)₄) precursor and water were used to deposit ZrO₂ thin films. Nitrogen was used to purge the deposition chamber and gas manifold for 30 s.

Analysis Techniques. For unpatterned film deposition on a reference sample, the elemental composition of the ZrO₂ was measured by X-ray photoelectron spectroscopy (PHI VersaProbe, Physical Electronics). For the patterned substrate, the topography was obtained by AFM and scanning electron microscopy (SEM). The elemental mapping was performed by Auger electron spectroscopy (PHI 700, Physical Electronics). All of the spectra shown herein have a detection sensitivity of <0.1 at. %.

Fabrication of ALD nano-structures requires smooth and densely packed ODTS layers. We found that the native oxide on the cleaned silicon wafers is ˜2 nm in thickness with a RMS roughness of less than 1 Å before SAM growth. The RMS roughness of ODTS layers on the native oxide was measured as less than 5 Å. A tapping mode AFM scan was used to measure RMS roughness to minimize the artifact from the damage to ODTS layers, which could lead to a smaller RMS roughness when a contact mode was used. The dipping time in ODTS solution was required to be more than 48 h to sufficiently block ZrO₂ precursors. The thickness of ODTS layers and the water contact angle reached values of 26 Å and 110°, which are consistent with previous reports.

The ALD blocking capability of ODTS was first explored with unpatterned substrates. A bare silicon substrate and ODTS-grown silicon substrate were introduced into the ALD chamber for 50 cycles of ALD ZrO₂. At each cycle, the substrate surface was exposed to (Zr(NMe₂)₄) precursors for 0.5 s and water for 0.5 s. After each exposure, nitrogen was used to purge the deposition chamber and gas manifold for 30 s to avoid possible gas-phase reactions. Assuming the bulk growth rate of 0.8 Å per cycle, the 50 cycles of ALD ZrO₂ would form a thin ZrO₂ film on a bare silicon substrate with a thickness of ˜40 Å.

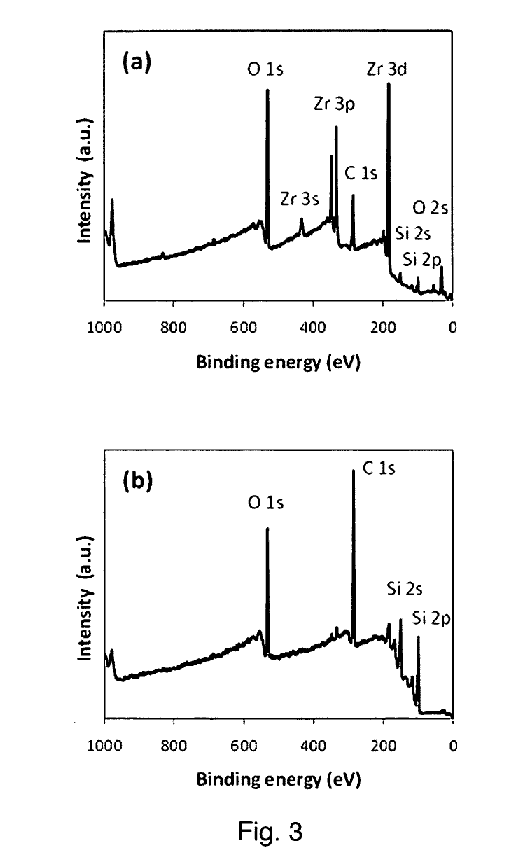

The XPS spectra in FIGS. 3a-b show the ZrO₂ deposition on the bare silicon wafer with a native oxide and an ODTS-grown silicon wafer with a dense ODTS layer. On the bare silicon wafer (FIG. 3a), clear Zr peaks were seen (15.2 at. %). There were, however, no Zr peaks on the ODTS-grown substrate (FIG. 3b) to within the sensitivity of the spectrometer (<0.1 at. %). The carbon concentration increased from 37.7 at. % on a bare silicon wafer to 57.6 at. % on the ODTS-grown substrate. These results confirm that a conformal and dense ODTS layer was formed on Si substrates, and that ODTS can be applied as an effective molecular resist against ZrO₂ ALD.

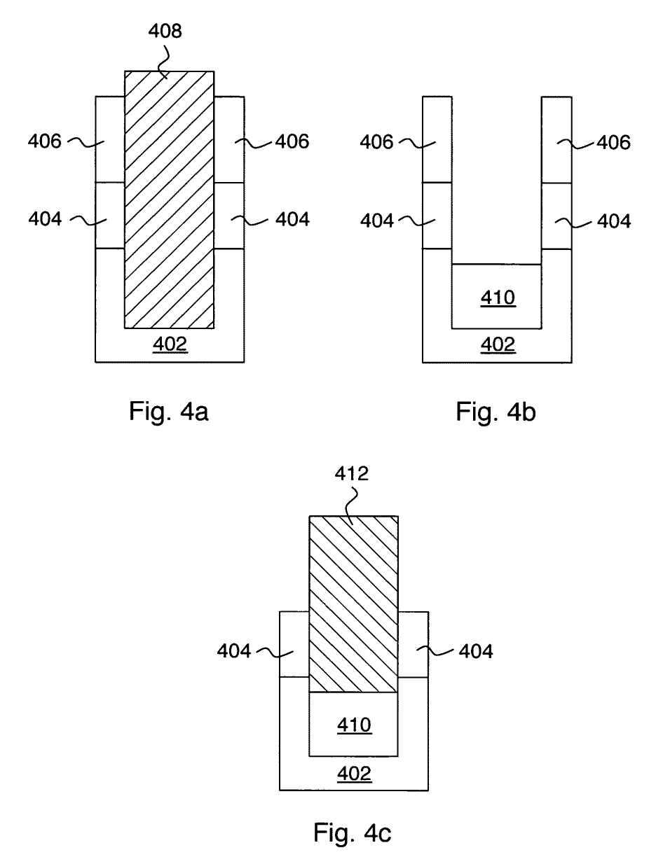

FIGS. 4a-c show a schematic cross-section at each step. Oxide patterns created by AFM oxidation lithography have an apparent height above the surface of ˜0.7 nm as shown in FIG. 4a. However, when the ODTS layer 406 (˜2.6 nm), native oxide 404 (˜2 nm), and volume loss in Si substrate 402 during the oxidation (˜2.4 nm) are considered, the total thickness of the oxide pattern 408 was ˜7.7 nm. Subsequent HF etching removed these oxide patterns, but native oxide 410 formed at the trench bottoms, resulting in an apparent depth of ˜5 nm (FIG. 4b). In FIG. 4c, although the apparent height of ALD pattern 412 was measured as ˜5 nm in the final structure after the ALD process and ODTS removal, the actual thickness of the ALD patterns was estimated to be ˜7.4 nm. The growth rate based on this model is ˜0.74 Å per cycle, which is in a good agreement with the typical growth rate of ZrO₂, 0.8 Å per cycle, obtained on a bare silicon wafer.

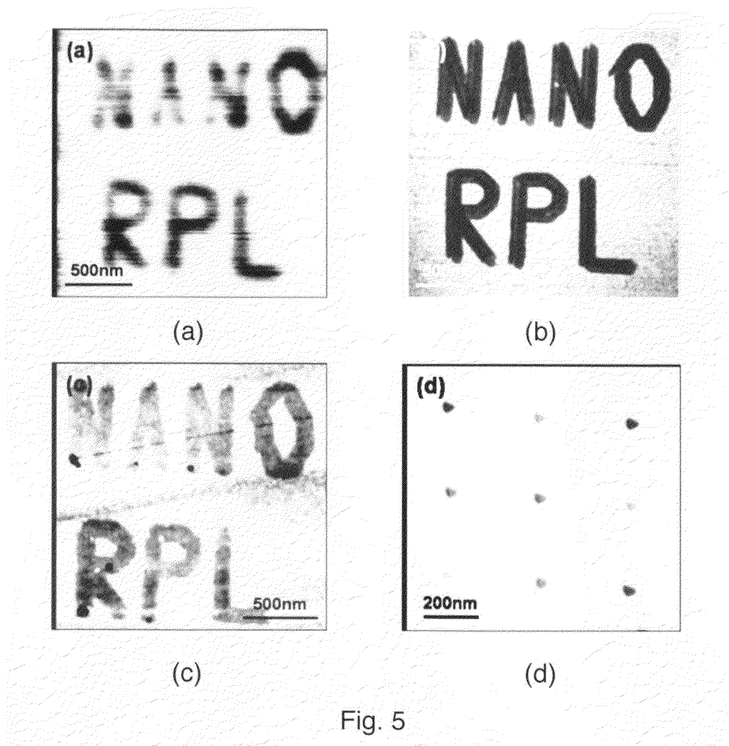

FIGS. 5a-d show the sequential AFM topography images of each step in the fabrication of ALD nano-structures. The positive patterns in FIG. 5a are oxide patterns created on an ODTS-grown substrate by AFM anodic oxidation. A contact mode and 10 V were used to create oxide patterns. The oxide starts growing from the interface between the silicon and native oxide layer, and the ODTS SAMs on the oxide patterns were removed. The height of oxide patterns on the ODTS-grown substrate was 7˜8 Å, whereas we obtained ˜4 nm with the same AFM oxidation conditions on a bare silicon wafer. This discrepancy can be explained by the thickness of the ODTS layer, which is ˜2.6 nm. The line width of these oxide patterns was ˜130 nm.

A diluted HF solution (50:1 HF for 2 min) was used to remove the oxide pattern, resulting in the negative pattern shown in FIG. 5b. The ODTS layer was not removed by HF etching; only the oxide patterns were selectively removed. The depth of the negative pattern was ˜5 nm, which is approximately the same as the sum of the ODTS thickness (˜2.6 nm) and the native oxide layer (˜2 nm). This minor discrepancy results from the volume loss of the silicon substrate during oxidation and the re-grown native oxide that occurred after oxide etching.

These pre-patterned samples were placed in an ALD chamber for ZrO₂ deposition. Since ODTS is a chemical resist for the ALD reaction, there will be no deposition where the ODTS monolayer is present, while ZrO₂ will be deposited on only the negative patterns where ODTS is removed by AFM oxidation and oxide etching. After 100 cycles of ZrO₂ ALD, an oxygen plasma etch was performed to remove the ODTS layer, leaving the ALD patterns on the silicon substrate. Consequently, ZrO₂ ALD nano-structures of ˜5 nm in height and ˜140 nm in line width were fabricated, as shown in FIG. 5c. The created nano-structure shows an excellent spatial resolution. The change of the line width of the final structures is less than ˜8%, when compared to the oxide width after AFM oxidation lithography.

FIG. 5d demonstrates another example (3×3 patterns with ˜5 nm in height) of ALD nano-structures with a diameter of ˜40 nm, the smallest pattern fabricated in this study. The lateral dimension of patterns can be easily controlled by AFM oxidation lithography from ˜40 nm to a few um in diameter. Due to the finite tip size, however, fabrication and characterization of smaller patterns is challenging. Downsizing of the ALD nano-structure could be achieved with a sharp and high-aspect ratio tip.

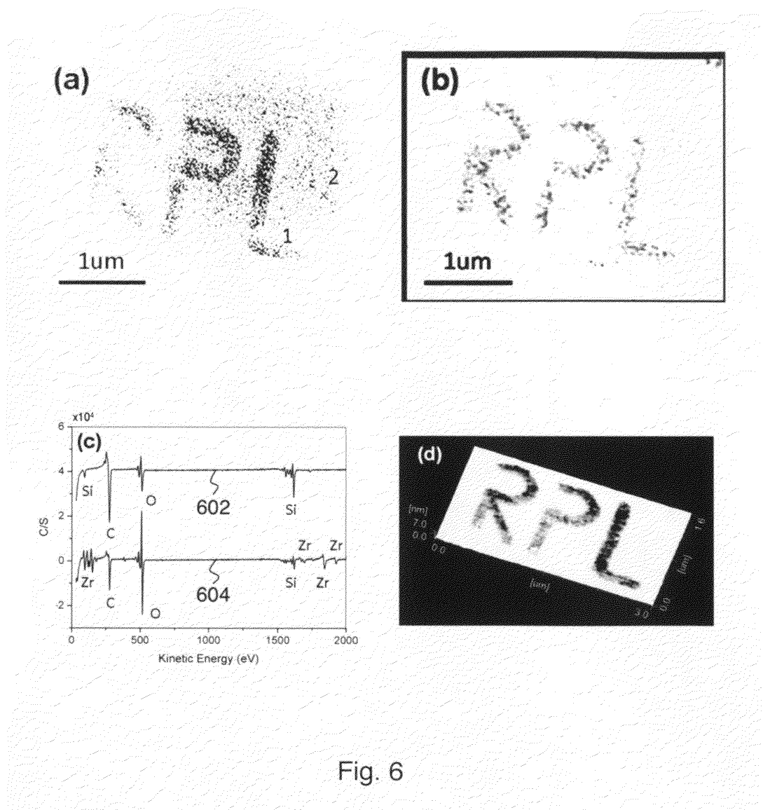

Auger electron spectroscopy (AES) was performed to confirm the chemical composition of the created ALD pattern. Relatively large patterns were created with a line width of ˜300 nm to conveniently identify patterns with SEM and to obtain a larger AES signal. An SEM image of the ALD pattern and Zr elemental map are presented in FIGS. 6a and 6b, respectively. The low contrast in the SEM image results from the insulating nature of the ZrO₂ patterns and the native oxide on the silicon substrate. This low conductivity limits the resolution of elemental mapping. The elemental map of FIG. 6b was acquired after 10 cycles of acquisition, although a greater number of cycles is typically used to get a higher signal-to-noise ratio, particularly at this scale. The drift that occurs during data acquisition is usually adjusted by image registration and correction during each cycle. But in this case, since the contrast in the SEM images was not sufficient to perform this drift correction function, the number of cycles was limited. However, even with the small amount of acquisition, the elemental map clearly shows the ZrO₂ patterns with a very high spatial resolution. A brighter contrast in the elemental map indicates a higher concentration of a trace element, Zr in this case.

In addition, survey scans at two areas, inside and outside the pattern, show an excellent selectivity for the ALD precursor, as shown in FIG. 6c. Zr peaks are clearly detected in curve 604 (taken at a location inside the pattern), while no distinguishable Zr peaks are detected in curve 602 (taken at a location outside the pattern) within the sensitivity of the spectrometer (<0.1 at. %). In addition, the oxygen concentration in curve 604 is higher because the pattern is ZrO₂. However, the carbon peak in curve 604 is smaller since this AES spectrum was obtained before ODTS removal. These results confirm the chemical composition of the ALD nano-structure as well as demonstrating an excellent spatial selectivity. A 3D topography taken by AFM is shown in FIG. 6d for comparison.

1. A method of performing area-selective atomic layer deposition, the method comprising:
depositing a self-assembled monolayer on a substrate;
selectively oxidizing said self-assembled monolayer by exposure to an electric field and/or an electric current from one or more scanning probe microscope tips to form a patterned substrate having an oxide pattern in said self-assembled monolayer;
performing atomic layer deposition (ALD) on said patterned substrate such that said atomic layer deposition occurs in an ALD pattern defined by said oxide pattern.

2. The method of claim 1, wherein said ALD pattern is substantially congruent to said oxide pattern.

3. The method of claim 1, wherein said ALD pattern is substantially congruent to an image negative of said oxide pattern.

4. The method of claim 1, wherein said atomic layer deposition is epitaxial.

5. The method of claim 1, wherein said atomic layer deposition is non-epitaxial.

6. The method of claim 1, wherein said scanning probe microscope tip is an atomic force microscope tip.

7. The method of claim 1, wherein said scanning probe microscope tip is a scanning tunneling microscope tip.

8. A method of performing area-selective atomic layer deposition, the method comprising:
depositing a self-assembled monolayer on a substrate;
selectively oxidizing said self-assembled monolayer by exposure to an electric field and/or an electric current from one or more scanning probe microscope tips to form an oxide pattern in said self-assembled monolayer;
removing said oxide pattern to form a patterned substrate having an exposed substrate pattern;
performing atomic layer deposition (ALD) on said patterned substrate such that said atomic layer deposition occurs in an ALD pattern defined by said exposed substrate pattern.

9. The method of claim 8, wherein said ALD pattern is substantially congruent to said exposed substrate pattern.

10. The method of claim 8, wherein said ALD pattern is substantially congruent to an image negative of said exposed substrate pattern.

11. The method of claim 8, wherein said atomic layer deposition is epitaxial.

12. The method of claim 8, wherein said atomic layer deposition is non-epitaxial.

13. The method of claim 8, wherein said scanning probe microscope tip is an atomic force microscope tip.

14. The method of claim 8, wherein said scanning probe microscope tip is a scanning tunneling microscope tip.
